(19) United States
(12) Patent Application Publication
(10) Pub. No.: US 2026/0187328 A1
(43) Pub. Date: Jul. 2, 2026

(54) SHAPE OVERLAP DETECTION FOR GENERATIVE LAYOUT DESIGN

(71) Applicant: NVIDIA Corporation, Santa Clara, CA (US)

(72) Inventors: Mark Jeffrey KILGARD, Austin, TX (US); David Zhao AKELEY, Sunnyvale, CA (US)

(73) Assignee: NVIDIA Corporation, Santa Clara, CA (US)

(21) Appl. No.: 19/008,210

(22) Filed: Jan. 2, 2025

(51) Int. Cl. G06F 30/3308; G06T 7/00; G06T 7/50

(52) U.S. Cl. CPC G06F 30/3308; G06T 7/0006; G06T 7/50; G06T 2207/30141; G06T 2207/30148; G06T 2207/30242

(57) ABSTRACT

In various examples, systems and methods are disclosed relating to quantifying the overlaps among a plurality of two-dimensional shapes. A system can identify a plurality of shapes for a circuit layout corresponding to an image. The system can allocate a stencil buffer for the image, the stencil buffer comprising a stencil sample for at least one point of the image. A system can generate, using the stencil buffer, an indication of a number of the plurality of shapes that overlap the at least one point. The overlap indications can inform alternative placements of the plurality of shapes for the circuit layout.

### BACKGROUND

Computer-aided design (CAD) software can be used to place and route components for circuit boards. Placing virtual components for a circuit board layout involves determining the optimal positions and orientations for each component while adhering to design constraints. It is challenging to efficiently determine placements for components so that connections (“traces”) between components can be successfully and efficiently routed and the components themselves have sufficient overlap-free separations needed for manufacturing.

### SUMMARY

This disclosure describes systems and methods that optimize component placement in circuit board layout processes using shape overlap detection. Conventional CPU-based approaches become inefficient as the number of components increases due to the high computational demands of comparing component shapes and constraints. To address the limitations of conventional approaches, the techniques described herein leverage the characteristics of stencil buffers implemented via graphics processing units (GPUs) to perform efficient overlap detection. Rather than implementing stencil buffers for rendering processes, the techniques described herein use stencil buffers to represent winding numbers for component footprints and enables the determination of overlapping regions. This technical solution provides approaches for overlap detection that cannot practically be performed using conventional CPU-based techniques.

At least one aspect relates to one or more processors. The one or more processors can include one or more circuits. The one or more circuits can identify a plurality of shapes for a layout plan corresponding to an image. The one or more circuits can allocate a stencil buffer for the image, the stencil buffer comprising a stencil sample for at least one point of the image. The one or more circuits can generate, using the stencil buffer, an indication of a number of the plurality of shapes that overlap the at least one point. The one or more circuits can modify the layout plan based at least on the indication of the number of the plurality of shapes that overlap the at least one point.

In at least one embodiment, the layout corresponds to a circuit layout, and the layout plan corresponds to the placement and position of the circuit components. However, while the present disclosure references circuit layouts, this is for example, non-limiting purposes only, and it should be understood that the layout and layout plans of the present disclosure can correspond to any arrangement of items, objects, components, etc. where precise positioning of components and/or accommodating constraints precisely is desirable. Additional, non-limiting examples of potential implementations may include implementations directed to planning a printed circuit board layout, an integrated circuit packaging design layout, a microchip design layout, a factory layout, a product layout in a retail environment; or an architecture structure layout.

In some implementations, the one or more circuits can generate a coverage image based at least on the image and the indication. In some implementations, the one or more circuits can determine, using an occlusion query, an estimate of an area of a first shape of the plurality of shapes that overlaps at least one second shape of the plurality of shapes. In some implementations, the one or more circuits can generate the stencil sample to include a winding number calculated for a first shape of the plurality of shapes with respect to the at least one point.

In some implementations, the one or more circuits can calculate the winding number based at least on the path corresponding to the first shape. In some implementations, the one or more circuits can encode the indication of the number of the plurality of shapes that overlap the at least one point, in the stencil sample of the stencil buffer corresponding to the at least one point. In some implementations, the indication comprises one of three states including (i) an indication that none of the plurality of shapes overlap the at least one point, (ii) an indication that one of the plurality of shapes overlap the at least one point, and (iii) an indication that two or more of the plurality of shapes overlap the at least one point.

In some implementations, the stencil buffer comprises a plurality of stencil samples respectively corresponding to each point of a plurality of points of the image. In some implementations, the one or more circuits can generate, for one or more stencil samples of the plurality of stencil samples, a respective indication of a number of the plurality of shapes that overlap a respective point of the plurality of points. In some implementations, the one or more circuits can generate the indication of the number of the plurality of shapes that overlap the at least one point based at least on a first winding number generated for a first shape of the plurality of shapes and a second winding number generated for a second shape of the plurality of samples.

At least one aspect relates to a system. The system can include one or more processors. The system can allocate a stencil buffer comprising a plurality of samples for an image comprising a plurality of shapes, at least one (e.g., each, every, etc.) sample of the plurality of samples corresponding to a respective position of the image. The system can update the at least one sample of the plurality of samples based on the plurality of shapes to generate an updated plurality of samples. The system can generate an estimated overlap area of at least two of the plurality of shapes based on the updated plurality of samples. The system can update a layout plan of the plurality of shapes based at least on the estimated overlap area.

In some implementations, at least one (e.g., each, every, etc.) sample of the plurality of samples comprises a first number of bits corresponding to a respective winding number. In some implementations, the system can update the respective winding number of a first sample of the plurality of sample based on a first shape of the plurality of shapes. In some implementations, the at least one sample of the plurality of samples comprises at least one bit corresponding to an overlap. In some implementations, the system can update the at least one bit of the first sample based on the respective winding number of the first sample. In some implementations, the system can generate the estimated overlap area based on an occlusion query of the stencil buffer. In some implementations, each of the plurality of shapes is defined as a filled path.

At least one aspect is related to a method. The method can include identifying, using one or more processors, a plurality of shapes for a layout plan corresponding to an image. The method can include allocating, using the one or more processors, a stencil buffer for the image, the stencil buffer comprising a stencil sample for at least one point of the image. The method can include generating, using the one or more processors, using the stencil buffer, an indication of a number of the plurality of shapes that overlap the at least one point.

In some implementations, the method can include generating, using the one or more processors, a coverage image based at least on the image and the indication. In some implementations, the method can include determining, using the one or more processors, using an occlusion query, an estimate of an area of a first shape of the plurality of shapes that overlaps at least one second shape of the plurality of shapes.

The processors, systems, and/or methods described herein can be implemented by or included in at least one of a control system for an autonomous or semi-autonomous machine, a perception system for an autonomous or semi-autonomous machine, a system for performing simulation operations, a system for performing digital twin operations, a system for performing light transport simulation, a system for performing collaborative content creation for 3D assets, a system for performing deep learning operations, a system for performing generative AI operations using a large language model, a system for performing generative AI operations using a video language model, a system implemented using an edge device, a system implemented using a robot, a system for performing conversational AI operations, a system for generating synthetic data, a system incorporating one or more virtual machines (VMs), a system implemented at least partially in a data center, or a system implemented at least partially using cloud computing resources.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems for performing generative AI operations, systems for performing operations using LLMs and/or VLMs, systems for performing light transport simulation, systems for performing collaborative content creation for 3D assets, systems implemented at least partially using cloud computing resources, and/or other types of systems.

Approaches in accordance with various embodiments can be used to generate one or more parameters for a content generation environment. In at least one embodiment, a trained machine learning (ML) and/or artificial intelligence (AI) system, such as a large language model (LLM) or a vision language model (VLM), may be used to generate parameters for the content generation environment, such as, but not limited to, camera settings, scene lighting, video parameters, and/or the like, used for displaying objects within a scene. The parameters may be based on an input provided by a user or a proxy for a user to a trained language model (e.g., LLM, VLM, etc.) that can then generate one or more settings in accordance with the input. Various embodiments may be used to generate settings in two-dimensional (2D) or three-dimensional (3D) settings. For embodiments that incorporate one or more language models—that is, one or more LLMs, one or more VLMs, or a combination of LLMs and VLMs, the language model(s) may receive an input (e.g., a prompt, a request, a query, etc.) that is parsed or otherwise formatted to generate a deterministic output. For example, the input provided to the language model may include a particular format for the output results, an example of desired output results, a particular list of parameters and their respective formatting, and the like. An input generator (e.g., a prompt generator), which may be driven or otherwise guided by one or more AI and/or ML systems, may be used to generate this input based on an initial input received from a user, a device, a proxy, and/or the like. A modified input generated by the input generator may then be provided to the language model, which will generate an output set of parameters. This output may be further evaluated with a reviewer, or other system, to ensure that the output is appropriate. Thereafter, a configuration file may be generated and/or the parameters may be directly provided to an environment to configure different components (e.g., camera settings, lighting, etc.) based on the parameters generated by the language model.

In some examples, the machine learning model(s) (e.g., deep neural networks, language models, LLMs, VLMs, multi-modal language models, perception models, tracking models, fusion models, transformer models, diffusion models, encoder-only models, decoder-only models, encoder-decoder models, neural rendering field (NERF) models, etc.) described herein may be packaged as a microservice—such an inference microservice (e.g., NVIDIA NIMs)—which may include a container (e.g., an operating system (OS)-level virtualization package) that may include an application programming interface (API) layer, a server layer, a runtime layer, and/or at least one model “engine.” For example, the inference microservice may include the container itself and the model(s) (e.g., weights and biases). In some instances, such as where the machine learning model(s) is small enough (e.g., has a small enough number of parameters), the model(s) may be included within the container itself. In other examples—such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs—such as REST APIs. As such, and in some embodiments, the machine learning model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications—such as NVIDIA's TensorRT), and/or enterprise management data for telemetry (e.g., including identity, metrics, health checks, and/or monitoring).

The machine learning model(s) described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the machine learning model(s) (e.g., that has been optimized for high performance inference), an inference runtime software to execute the machine learning model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the machine learning model(s). When replacing or updating, the software that performs the replacement/updating may maintain user configurations of the inference runtime software and enterprise management software.

### BRIEF DESCRIPTION OF THE DRAWINGS

The present systems and methods for implementing shape overlap detection for generative layout design are described in detail below with reference to the attached drawing figures, wherein:

FIG. 1 is a block diagram of an example system for implementing shape overlap detection using graphics processors, in accordance with some embodiments of the present disclosure;

FIG. 2 depicts an example diagram showing a resulting output of the shape overlap detection techniques described herein, in accordance with some embodiments of the present disclosure;

FIG. 3 is a flow diagram of an example of a method for implementing shape overlap detection, in accordance with some embodiments of the present disclosure;

FIG. 4 is a block diagram of an example computing device suitable for use in implementing some embodiments of the present disclosure; and

FIG. 5 is a block diagram of an example data center suitable for use in implementing some embodiments of the present disclosure.

### DETAILED DESCRIPTION

This disclosure relates to systems and methods for implementing shape overlap detection to optimize placement of components for circuit board layout processes. One step in circuit board layout involves determining the optimal positions of different components while satisfying the tolerances specified in design rules for the circuit board. Design rules are used to ensure the circuit board operates as intended. Automatic circuit board design processes use algorithms to automatically place components on a virtual circuit board that their virtual footprints to not violate these design rules. The system and methods described could also be applied to meet shape placement requirements for integrated circuit package, chiplet, and Application Specific Integrated Circuit (ASIC) design.

To properly place potentially hundreds or thousands of components on a circuit board in a manner that does not violate design constraints, overlap detection is implemented using the virtual footprints of each component. Shape overlap detection is used to determine whether components placed on a virtual circuit board are overlapping other components or violate any design rules for the circuit board. Conventional approaches for overlap detection are generally implemented using CPU-based approaches. However, CPU-based approaches for detecting overlaps between shapes becomes impracticable to perform as the number of circuit board components increases, as the computational resources to perform the comparisons needed are quickly exhausted.

To address these limitations, the systems and methods described herein implement a parallelizable approach to overlap detection that leverages the distributed computing capabilities of one or more graphics processing units (GPUs). The overlap detection techniques described herein can be used to detect overlap in any type of shape or device footprint, including but not limited to bounding boxes, circles, or complex shapes with holes or curves.

To implement GPU-based overlap detection, stencil buffers that correspond to shapes representing the device footprints of circuit board components are used. Each stencil sample of a stencil buffer representing a shape can include information relating to whether the corresponding component is covered by a single shape, covered by two or more shapes, and information relating to the winding number for the stencil sample.

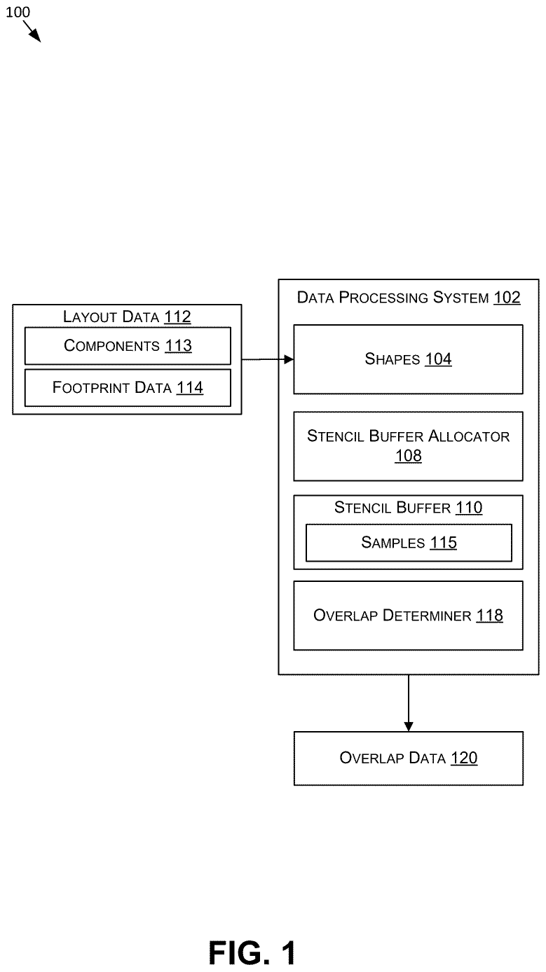

With reference to FIG. 1, FIG. 1 is an example computing environment including a system for implementing shape overlap detection, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

The system 100 can be utilized to identify overlap between one or more shapes 104 identified from layout data 112. The system 100 is shown as including a data processing system 102, layout data 112, and overlap data 120. The layout data 112 is shown as including or otherwise being associated with at least one component 113. The data processing system 102 includes one or more shapes 104, a stencil buffer allocator 108 (sometimes referred to as an “allocator 108”), at least one stencil buffer 110, and an overlap determiner 118. Although shown as being external to the data processing system 102, the layout data 112 and/or the overlap data 120 may be stored in memory of the data processing system.

The data processing system 102 can include any type of computing device that can perform layout operations for circuit boards. For example, the data processing system 102 may be computer that executes computer-aided design (CAD) software. The data processing system 102 may include, but is not limited to, one or more personal computers, a tablet device, a laptop, a smartphone device, a server in communication with one or more client devices, or a distributed computing environment, among others. The data processing system 102 can receive or otherwise identify layout data 112 from one or more processes, external computing devices, network requests, regions of memory of the data processing system 102, or other sources of information.

The layout data 112 may be generated by and received/identified from CAD software. The layout data 112 can include or may represent a layout for one or more printed circuit boards (PCBs). The layout data 112 can identify locations for component placement, interconnections, and routing paths. The layout data 112 can include information identifying one or more circuit components 113 and corresponding footprint data 114 (sometimes referred to herein as “footprint(s) 114”) for the one or more circuit components 113. Information for each component 113 can include or be associated with location data (e.g., relative or absolute location information for the component 113 in the PCB layout), which may include the location, orientation, and size/footprint of each component 113. As used herein, components 113 (and the footprints 114 that correspond thereto) can represent electrical components (e.g., resistors, capacitors, inductors, transistors, integrated circuits, etc.), traces, power/ground planes, and/or connectors, among others that are positioned in corresponding locations on a circuit layout. In some implementations, the layout data 112 and/or the footprint data 114 can include information specifying the location and orientation of the one or more components 113, including traces, ground/power planes, or electrical contacts, among others.

Different components 113 identified within the layout data 112 can be represented with distinct footprints 114, which can reflect size, dimensions, area, and portions of a corresponding component 113 that contact the PCB. A footprint 114 can define the area that the component 113 physically occupies on the PCB. In some implementations, the footprint 114 may be larger than the actual component 113 to ensure that design rules for the PCB are not violated during component 113 placement. In such implementations, the footprint 114 can be a region of the PCB dedicated to the corresponding component 113 and which cannot be occupied by any other component 113. The footprints for each component may be stored in association with a corresponding identifier of the component in the layout data 112. In implementations where the data processing system 102 executes CAD software, the data processing system 102 can modify the layout data 112 (e.g., modify component positions, orientations, or properties) in response to corresponding interactions with graphical user interface(s) of the CAD software.

The data processing system 102 can access the layout data 112 to determine whether the footprints 114 of any two (or more) components 113 overlap with one another. To do so, the data processing system 102 can convert the footprints 114 of the components 113 of the layout data into one or more shapes 104 stored in memory of the data processing system 102. Converting the footprints 114 into shapes can include generating one or more filled paths for each component 113 in the layout information and storing the data of each path in the memory of the data processing system 102. Each filled path can be a set of connected line segments that form a closed loop (for filled areas) or an open outline. Each shape 104 can include vertices and one or more edges connected to the vertices to define at least one outline of the shape 104 defined in a 3D space corresponding to the layout 112 of the circuit.

In some implementations, the layout data 112 can store a representation of the circuit layout as a vector image, with the footprint 114 of each component 113 being stored as a vector graphic or in a vector format (e.g., as a shape 104). The shapes 104, as described herein, can be stored in as a set of piecewise continuous contours to define a filled path. In such implementations, the data processing system 102 can directly retrieve the vector format footprint 114 of each component 113 as a piecewise continuous filled path representation and store the filled path as a corresponding shape 104. In some implementations, the layout can be defined as an image with one or more layers, where each layer comprises a region of pixels representing the footprint of a respective component 113. In such implementations, the data processing system 102 can use a vectorization process or an image tracing process to convert the pixels representing each footprint 114 into a corresponding filled path representation.

In some implementations, the data processing system 102 can convert the layout data 112 into a vector image or vector data in memory of the data processing system, with each footprint 114 converted into a respective shape 104 and represented as a filled path. The vector image/vector data can be accessed by the components of the data processing system 102 to perform further operations, including identifying overlapping regions between shapes 104 and estimating the total overlapped area between two or more shapes 104.

The data processing system can execute the stencil buffer allocator 108 to allocate a stencil buffer 110 for the shapes 104 extracted/retrieved from the layout data 112. The stencil buffer allocator 108 can include software, hardware, or combinations of hardware and software. To allocate the stencil buffer the stencil buffer allocator 108 can access application programming interfaces (APIs) or function calls corresponding to one or more graphics processing units (GPUs) to reserve at least one contiguous block of memory within the address space of the one or more GPUs for performing stencil operations. The stencil buffer 110 can be allocated to include a plurality of samples 115, with each sample 115 corresponding to a respective pixel of a rasterization of the layout data 112. Each sample 115 (sometimes referred to as a “pixel” or “point”) in the stencil buffer 110 can include one or more numerical values that may be manipulated at the bit-level by various stencil operations described herein.

The stencil buffer allocator can allocate the stencil buffer 110 such that a predetermined number of bits in each sample/pixel/point 115 are dedicated to a winding number for the corresponding pixel 115. Each sample 115 can include at least one bit that represents an indication that at least one shape 104 overlaps the corresponding sample 115 and at least one bit that represents an indication that at least two shapes 104 overlap the corresponding sample 115. In some implementations, the bits that indicate overlap can be the most significant bits in the sample 115 and the winding number can be the least-significant bits in the sample 115. In some implementations, different bit arrangements may be implemented (e.g., the winding number stored in the most significant bits, the overlap bits in the least-significant bits, etc.). Further, other implementations are contemplated in which the overlap indications are stored in different data structures, such as bytes or words.

Allocating the stencil buffer 110 may include storing information about the footprints of each component 113 in one or more regions of memory of the data processing system 102. For example, this may include storing the vertices/paths for each shape 104 extracted/retrieved from the layout information 112 in one or more data structures in memory of the data processing system 102. The stencil buffer 110 can be allocated such that each sample 115 of the stencil buffer 110 respectively corresponds to a respective pixel of the circuit image extracted/retrieved from the layout data 112. The shapes 104 can be stored in association with location/orientation information (e.g., for each vertex/edge) such that the position(s) of each shape can be mapped to corresponding sample(s) 115 of the stencil buffer 110 (e.g., through rasterization, etc.). In some implementations, the stencil buffer allocator 108 can provide information relating to the vertices/paths for each shape 104 for storage in memory of one or more GPUs of the data processing system 102. The data processing system 102 (or the components thereof) can execute one or more stencil operations to detect overlap between two or more shapes 104, as described in further detail herein.

The data processing system 102 can execute the overlap determiner 118 to generate, using the stencil buffer 110, respective indications of the number of the plurality of shapes that overlap each sample/point 115 in the stencil buffer 110. The indication may be stored, for example, as one or more overlap bits in each sample 115. For example, one overlap bit may be set to a ‘1’ value when it is determined that one shape 104 overlaps the corresponding sample 115. Furthering this example, another overlap bit may be set to a ‘1’ value when it is determined that two or more shapes overlap the corresponding sample 115. To do so, the overlap determiner 118 can execute one or more stencil operations for each shape 104 to update the samples 115.

The stencil operations can include “stencil” and “cover” operations performed for each shape. As described herein, each shape 104 can be defined as a piecewise continuous filled path. For the following description, C is used to denote the filled path of a given shape 104, and each interval of the piecewise representation of the path C can be referred to as a link L and can be continuous but need not be discontinuous. The stencil operation executed by the overlap determiner 118 to calculate a respective winding number for each sample 115 with respect to the path C (e.g., the shape 104 for which the stencil operation is being performed). Bits of the sample 115 used for the winding number may be referred to as the winding number bits W. The winding number can be calculated such that the winding number bits W of each sample 115 are incremented and wrapped.

Various configuration operations for the stencil operation, including configuring masks or other aspects of the stencil operation, can be performed by accessing one or more application programming interfaces (APIs) or low-level driver functions of the one or more GPUs storing the stencil buffer 110. The overlap determiner 118 can execute the stencil operation to update the winding number bits of each sample 115. To ensure that only the winding number bits W of the sample 115 are modified, the overlap determiner 118 can access one or more APIs for driver functions of the one or more GPUs to update a stencil write mask for the stencil buffer 110. A stencil write mask allows selective modification of bits within each stencil sample during a stencil operation. This mask, represented as a bit pattern, specifies which bits are written and which are preserved.

Updating the stencil write mask for a stencil buffer can include generating/providing a bitmask that indicates which bits of each stencil sample can be written or modified during the stencil operation. Bit masks can be generated/provided for each sample 115 of the stencil buffer 110. Each bit in the bit mask can correspond to a respective bit of the corresponding sample 115, where bits set to “1” in the stencil write mask indicate that the respective bit of the sample 115 can be updated/modified during stencil operations. For example, if the winding number bits W are the least significant bits of each sample 115, the overlap determiner 118 can access one or more APIs or driver functions of the one or more GPUs to update the stencil mask(s) to set the low W bits to “1”, and all other bits to “0”. Similar approaches can be implemented if the winding number bits W occupy different bits in each sample 115, such as the most significant bits.

Once the stencil write mask has been configured, the overlap determiner 118 can update the winding number bits W of each with an incremented-and-wrapped winding number for a given shape 104 by rasterizing triangles extending from a fill pivot point p_{f} for a (e.g., each, every, etc.) contour of the shape 104. A shape 104 may have multiple contours because the shape has one or more holes, multiple discontiguous regions, and/or multiple overlapping regions. The fill pivot point p_{f} of a contour of shape 104 can be selected as a point positioned within and roughly approximate to the center of that contour of the corresponding shape 104. In some implementations, the per-contour fill pivot point p_{f} can be specified as part of the footprint data 114. In some implementations, the overlap determiner 118 can automatically determine a (e.g., each, every, etc.) fill pivot point p_{f} based on the relative location of each vertex and/or link of each particular contour of the path C corresponding to the shape 104. A (e.g., each, every, etc.) fill pivot point p_{f} can be used as a central vertex of a sequence of triangles, or a triangle fan, that extends outward toward the edges of the pivot's respective contour belonging to the path C and are rasterized to update the winding number bits W of each sample 115 in the stencil buffer 110.

Rasterizing the set of triangle fans for a shape 104 can include defining the vertices of the triangle fan such that the triangles collectively approximate the footprint 114 of the component 113 corresponding to the shape 104. As noted above, a given shape 104 can be defined as a path C including a number of links L. To generate the triangles for a triangle fan, the overlap determiner 118 can quantize each link L of a given contour of the path C into a sequence of control points, such that the link L=l₀, l₁, . . . l_{w}. The control points l₀, l₁, . . . l_{w} are selected such that they closely approximate the original path C and are used as vertices for the triangle fan/sequence of triangles that is to be rasterized to update the winding numbers of the samples 115 of the stencil buffer 110. In some implementations, a predetermined number of control points can be selected/generated that fall on each link of the path C of the shape 104.

In some implementations, the number of control points selected for a link can be a function of the length of the link (e.g., with more control points generated for longer links, and relatively fewer points generated for shorter links). In some implementations, the number and arrangement of control points can be a function of the geometry of the link. For example, for linear/line segment links L, the overlap determiner 118 may generate/select fewer control points relative to a link that includes one or more arcs or curves. Selecting/generating a greater number of control points for arcs/curves enables the overlap determiner 118 to generate a triangle fan that better approximates the geometry of the path C, once the triangles are rasterized. Likewise, for portions of a link L that have a relatively greater curvature, the control points may be selected/generated for the link L can be positioned closer together relative to control points selected for a link defined as a line segment.

Once the control points l₀, l₁, . . . l_{w} for a (e.g., each, every, etc.) contour of the path C have been generated, the overlap determiner 118 can automatically generate/define a set of triangles that extend from the fill pivot point p_{f} for the contour to the control points l₀, l₁, . . . l_{w}. The set of triangles can be defined as a triangle fan with the fill pivot point p_{f} as defined the center vertex of each triangle and the control points as the outer vertices of the fan. In this arrangement, each triangle can share at least one side with at least one other triangle forming the triangle fan. Each triangle can be defined with the fill pivot point p_{f} as the first vertex and corresponding control points as second and third vertex. The order of the second and third vertices can follow the direction of a (e.g., each, every, etc.) contour of the path C. In some implementations, a portion of a path C defining the outer boundary of a shape 104 can have a clockwise direction, and a portion of a path defining an inner boundary of a shape 104 (e.g., an inner hole, etc.) can have a counterclockwise direction.

The order in which the vertices of a triangle are specified can indicate whether a triangle has a clockwise (or positive) orientation or a counterclockwise (or negative) orientation. The order of the control points can be selected such that a triangle fan defined for the outer path C of a shape 104 results in positively oriented triangles and such that a triangle fan defined for an inner path of a shape 104 (if any) results in negatively oriented triangles. Defining both positively and negatively oriented triangles for different types of paths enables the winding number of a sample 115 to correctly reflect whether the sample 115 is positioned within the shape 104, as described in further detail herein. The overlap determiner 118 can generate/define the triangles in memory of the one or more GPUs using one or more APIs or driver functions of the one or more GPUs that store the stencil buffer 110. The position of the triangles can correspond to the position of the shape 104 to which they correspond.

Once defined, the overlap determiner 118 can rasterize each of the triangles for the shape 104 according to the stencil operation. Rasterizing the triangles can include executing one or more rasterization functions of the API(s)/drivers of the one or more GPUs and can cause the winding number of each sample 115 to be updated. Pixels (samples 115) identified as falling within a given triangle are processed by the one or more GPUs of the data processing system 102 using the stencil operation, to increment-and-wrap the winding number bits W for each sample 115 that is covered by a positively oriented triangle and decrement-and-wrap the winding number bits W for each sample 115 that is covered by a negatively oriented triangle. The increment-and-wrap operation causes the winding number bits to “wrap around” to the minimum value if incrementing the bits by one would exceed the maximum allowed value of the winding number bits W. Likewise, the decrement-and-wrap operation causes the winding number bits to “wrap around” to the maximum value if decrementing the bits by one would exceed the maximum value of the window number bits W. In one example, each sample 115 can include 8 bits, with the lower 6 bits being the winding number bits W. The stencil operation has results in each sample 115 storing in its winding number bits W the winding number modulo 2^{W} of that sample 115 location with respect to the corresponding path C.

Once the stencil operation has been performed, each sample 115 is populated with a winding number that accurately reflects whether the sample 115 is positioned within a corresponding shape 104. The overlap determiner 118 can then execute a cover operation for the stencil buffer to generate an indication of a number of shapes 104 that overlap each sample 115. As described herein, each sample 115 can include at least one bit indicating that the sample 115 overlaps at least one shape 104, and at least one bit indicating that the sample 115 overlaps at least two shapes 104. These bits can be referred to as overlap bits b₁ and b₂, respectively, of the sample 115. The cover operation for the stencil buffer can include generating/defining one or more triangles that are large enough to cover at least all samples 115 modified by the prior stencil operation for the path C to perform a stencil test.

Subsequent cover operations can be used to set the bit b₁ to “1” for each sample having a non-zero winding number. Prior to modifying the bit b₁, the overlap determiner 118 can execute a cover operation to test whether the bit b₁ for each sample 115 is already set to “1” for each sample 115 having a non-zero winding number, indicating that a prior iteration of the process has determined that the sample 115 overlaps at least one other shape 104. For each sample that passes this stencil test (e.g., overlaps at least two shapes), the bit b₂ of the sample 115 can be set to “1”, indicating that the sample 115 is overlapped by at least two shapes. After this stencil test, the cover operation can cause the winding bits W to be reset to “0”. Similar techniques can be used to generate indications of the number of shapes 104 that overlap the sample 115. In one example, the sample 115 may include bits used as a counter that increments each time the sample 115 is determined to have a non-zero winding number, to count the number of shapes 104 that overlap the sample 115.

In further explanation of an implementation where bits b₁ and b₂ are used instead of a counter, after updating the bit b₂ for each sample 115 that is determined to already overlap at least one shape (or the counter, in some implementations) and setting the corresponding winding number bits to zero, the overlap determiner 118 can execute a subsequent cover operation with a stencil test for each sample 115 having non-zero winding bits W. For each sample 115 passing this stencil test, the bit b₁ can be set to “1”, indicating that the sample 115 is overlapped by at least one shape 104. Samples 115 that pass this stencil test (e.g., samples 115 that are overlapped by a shape 104) can have their winding number bits set to zero as part of the cover operation.

Prior to performing the foregoing cover operations, the overlap determiner 118 can modify the stencil mask such that the upper bits (or other bits outside of the winding number bits W) can be modified. Doing so enables the overlap determiner 118 to modify the upper bits b₁ and b₂, in addition to zeroing the winding number bits W for each passing sample 115. The overlap determiner 118 can execute the cover operations for the stencil buffer 110 using one or more APIs and/or driver functions of the one or more GPUs that store the stencil buffer 110. This process of executing stencil operations and cover operations can be repeated for each shape 104 (e.g., each path C), resulting in the bits b₂ for each sample 115 of the stencil buffer 110 that are overlapped by two or more shapes 104 being set to “1”. In this example, the bit b₂ and the bit b₁ can be an indicator of a number of shapes that overlap a given sample 115 in the stencil buffer. In some implementations, each sample 115 in the stencil buffer can include an indication (e.g., the bits b₂ and b₁, a counter value in some implementations) in one of three states. The three states may include an indication that none of the shapes 104 overlap the at least one sample 115 (e.g., bits b₂ and b₁ are set to “0”, an indication that one or more shapes 104 overlap the at least one sample 115 (e.g., the bit b₁ is set to “1”), and an indication that two or more shapes 104 overlap the at least one sample 105 (e.g., the bit b₂ being set to “1”).

The overlap determiner 118 can repeatedly update the samples 115 of the stencil buffer 110 for each path C of each shape 104 according to the techniques described herein. Once the samples 115 have been updated for all shapes 104, each sample 115 of the stencil buffer 110 that is overlapped by at least two shapes 104 has at least one bit b₂ set to “1”. Likewise, all samples 115 that overlap a single shape 104 can have the at least one bit b₁ set to “1” and the at least one bit b₂ set to “0”. In some implementations, the samples 115 include a counter that indicates the number of shapes 104 that overlap the sample 115. In some implementations, the overlap determiner 118 can use the values stored in each sample 115 of the stencil buffer 118 to generate a cover image. As described herein, the samples 115 can each correspond to a respective pixel of the circuit layout reflected in the layout data 112. The coverage image can be generated by extracting the bits b₁ and b₂ into an image/frame buffer, converting the values of the bits b₁ and b₂ into corresponding colors for the coverage image. For example, samples 115 in the stencil buffer 110 that do not overlap any shape 104 can be assigned a first color, samples 115 that overlap one single shape 104 can be assigned a second color, and samples 115 that overlap two or more shapes 104 can be assigned a third color.

In some implementations, the overlap determiner 118 can use the data stored in the samples 115 of the stencil buffer 110 to determine an estimated area (e.g., number of pixels in the circuit layout image of the layout data 112) of the overlap between at least two shapes 104. To do so, the overlap determiner can access the stencil buffer 110 and count the number of samples 115 having the bit(s) b₂ set to “1”. The total number of pixels/samples 115 that have the bit(s) b₂ set to “1” can closely approximate the total overlap area between at least two shapes 104 in the circuit layout. In some implementations, the overlap determiner 118 can use an occlusion query over the stencil buffer 110 to access the samples 115 to determine the total number of pixels/samples 115 that have the bit(s) b₂ set to “1”.

The data processing system 102 can provide the coverage image and/or the estimated area as part of the output data 120. The output data 120 may be provided, for example, to one or more CAD processes and/or provided for display via one or more output devices (e.g., display devices) of the data processing system 102. In some implementations, the data processing system 102 can receive layout data 112 from and provide corresponding output data 120 to one or more client devices. In such implementations, the data processing system 102 can receive the layout data 112 via a network, process the shapes 104 of the layout data 112 to identify overlapping portion(s) (e.g., generate a coverage image, generate an overlap estimate, etc.). In some implementations, the data processing system 102 can provide a representation (e.g., one or more data structures) of the stencil buffer 110 as part of the output data 120.

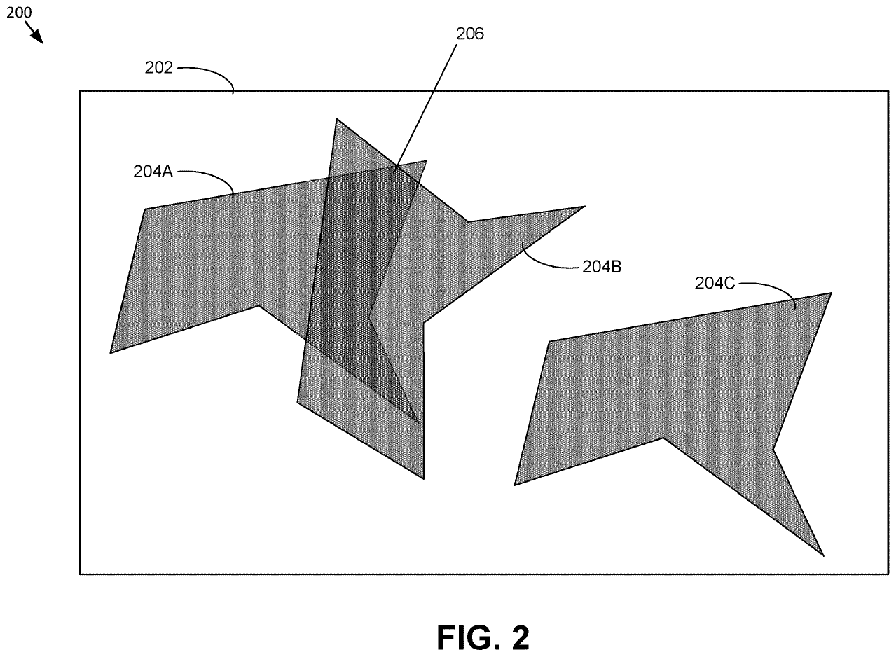

In the context of circuit layout determination, the techniques described herein can be used to calculate the overlap between footprints 114 of components 113 in a circuit layout. Footprints 114 that overlap can indicate a violation of one or more design rules for the layout 112. In some implementations, the data processing system 102, upon detecting an overlap of at least two footprints 114 described herein, can provide an indication that at least one design rule of the layout 112 has been violated. The indication may be provided as an error notification, a popup, or may be indicated in part using the coverage image of the output data 120. An example coverage image is shown in FIG. 2.

Referring to FIG. 2 in the context of the components described in connection with FIG. 1, depicted is an example diagram 200 showing a resulting output of the shape overlap detection techniques described herein, in accordance with some embodiments of the present disclosure. In this example, an image 202 shows three shapes 204A, 204B, and 204C (sometimes referred to generally as “shapes 204”), which can be similar to the shapes 104 described in connection with FIG. 1. In this example, the image 202 is a coverage image generated using the techniques described herein. The coverage image 202 includes pixels having a first color corresponding to the regions covered by each of the shapes 204. In this example, portions of the shape 204A overlap the portions of the shape 204B, reflected as the overlapping region 206. As shown, the overlapping region 206 is shaded with a different color relative to the portions of the coverage image 202 occupied only by a single shape 204. A third color (white, in this example) is used to indicate regions of the coverage image 202 that are not occupied by any shape 204.

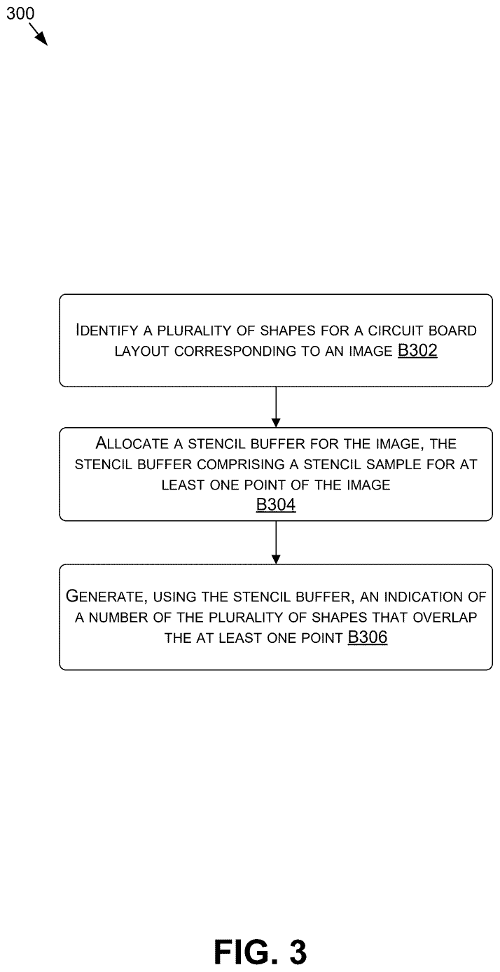

Now referring to FIG. 3, each block of method 300, described herein, includes a computing process that may be performed using any combination of hardware, firmware, and/or software. For instance, various functions may be carried out by one or more processors executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 300 is described, by way of example, with respect to the system of FIG. 1. However, this method may additionally or alternatively be executed by any one system, or any combination of systems, including, but not limited to, those described herein.

FIG. 3 is a flow diagram showing a method 300 for implementing shape overlap detection, in accordance with some embodiments of the present disclosure. The method 300, at block B302, includes identifying a plurality of shapes (e.g., the shapes 104) for a circuit board layout (e.g., the layout data 112) corresponding to an image (e.g., a vector image extracted from the layout data 112). The shapes can be identified vector images from the layout data 112 as piecewise continuous paths (e.g., the paths C), as described herein. Identifying the shapes can include receiving or accessing the circuit layout information from one or more CAD processes, from one or more client devices, or from memory of the computing system performing the method 300 (e.g., the data processing system 102). In some implementations, the shapes 104 can be generated from image data, vector data, and/or footprint data (e.g., footprint(s) 114) specified in the layout data 112.

The method 300, at block B304, includes allocating a stencil buffer (e.g., the stencil buffer 110) for the image representing the circuit layout comprising one or more stencil samples (e.g., the samples 115) for at least one point/pixel of the image. The stencil buffer can be allocated using one or more APIs and/or driver functions of one or more GPUs. The GPUs may be included as part of, or in communication with, the computing system performing the method 300. In some implementations, allocating the stencil buffer can include setting all bits of each sample of the stencil buffer to “0”. In some implementations, the data processing system can use one or more APIs and/or driver functions to initialize at least one stencil mask for subsequent stencil/cover operations, as described herein. The stencil mask can indicate which bits of each stencil sample can be written to during stencil/cover operations.

The method 300, at block B306, includes generating, using the stencil buffer, an indication of a number of the plurality of shapes that overlap the at least one point represented in the stencil buffer. As described herein, the indication may be provided in part by one or more bits of each stencil sample, as each stencil sample corresponds to a respective pixel/point of an image of the circuit layout. For example, the indication may include the bit b₂ and/or the bit b₁. Generating the indication may be performed by executing one or more stencil operations and one or more cover operations, as described in connection with the overlap determiner 118 of FIG. 1. In some implementations, a stencil operation can include rasterizing a triangle fan for a shape to update the winding number bits of each stencil sample. The winding number bits can be used to update the bits b₁ and/or b₂ of each sample using one or more cover operations, as described herein, to indicate the number of shapes the overlap each sample. Further stencil/cover operations can be executed to generate at least one coverage image using the stencil buffer. In some implementations, an estimate of the pixel area of the image can be estimated using an occlusion query over the stencil buffer, as described herein.

The systems and methods described herein may be used for a variety of purposes, by way of example and without limitation, for circuit layout definition, machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational artificial intelligence (AI), light transport simulation (e.g., ray-tracing, path tracing, etc.), collaborative content creation for three-dimensional (3D) assets, cloud computing, generative AI, and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models - such as one or more large language models (LLMs), systems for performing light transport simulation, systems for performing collaborative content creation for 3D assets, systems implemented at least partially using cloud computing resources, and/or other types of systems.

### Example Computing Device

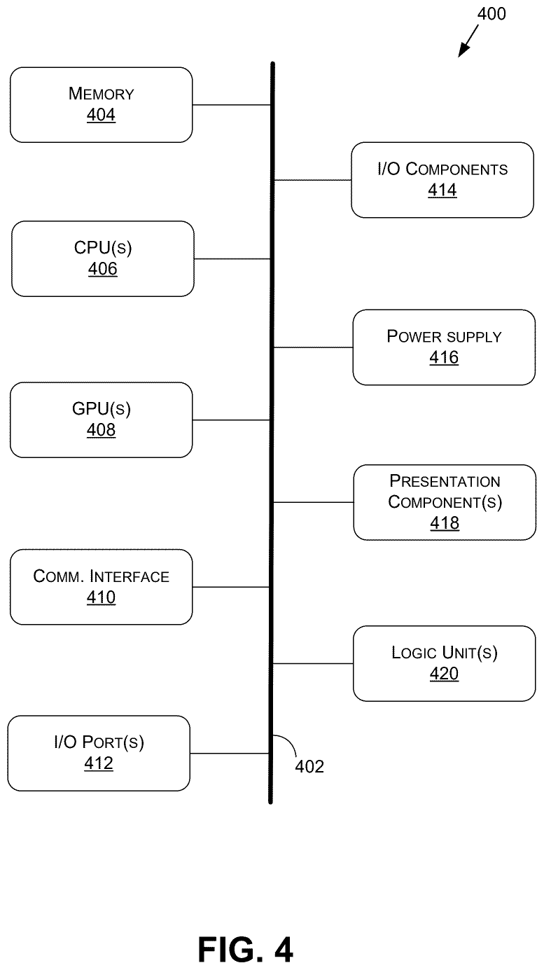

FIG. 4 is a block diagram of an example computing device(s) 400 suitable for use in implementing some embodiments of the present disclosure. Computing device 400 may include an interconnect system 402 that directly or indirectly couples the following devices: memory 404, one or more central processing units (CPUs) 406, one or more graphics processing units (GPUs) 408, a communication interface 410, input/output (I/O) ports 412, input/output components 414, a power supply 416, one or more presentation components 418 (e.g., display(s)), and one or more logic units 420. In at least one embodiment, the computing device(s) 400 may comprise one or more virtual machines (VMs), and/or any of the components thereof may comprise virtual components (e.g., virtual hardware components). For non-limiting examples, one or more of the GPUs 408 may comprise one or more vGPUs, one or more of the CPUs 406 may comprise one or more vCPUs, and/or one or more of the logic units 420 may comprise one or more virtual logic units. As such, a computing device(s) 400 may include discrete components (e.g., a full GPU dedicated to the computing device 400), virtual components (e.g., a portion of a GPU dedicated to the computing device 400), or a combination thereof.

Although the various blocks of FIG. 4 are shown as connected via the interconnect system 402 with lines, this is not intended to be limiting and is for clarity only. For example, in some embodiments, a presentation component 418, such as a display device, may be considered an I/O component 414 (e.g., if the display is a touch screen). As another example, the CPUs 406 and/or GPUs 408 may include memory (e.g., the memory 404 may be representative of a storage device in addition to the memory of the GPUs 408, the CPUs 406, and/or other components). In other words, the computing device of FIG. 4 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 4.

The interconnect system 402 may represent one or more links or busses, such as an address bus, a data bus, a control bus, or a combination thereof. The interconnect system 402 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 406 may be directly connected to the memory 404. Further, the CPU 406 may be directly connected to the GPU 408. Where there is direct, or point-to-point connection between components, the interconnect system 402 may include a PCIe link to carry out the connection. In these examples, a PCI bus need not be included in the computing device 400.

The memory 404 may include any of a variety of computer-readable media. The computer-readable media may be any available media that may be accessed by the computing device 400. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 404 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 400. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 406 may be configured to execute at least some of the computer-readable instructions to control one or more components of the computing device 400 to perform one or more of the methods and/or processes described herein. The CPU(s) 406 may each include one or more cores (e.g., one, two, four, eight, twenty-eight, seventy-two, etc.) that are capable of handling a multitude of software threads simultaneously. The CPU(s) 406 may include any type of processor and may include different types of processors depending on the type of computing device 400 implemented (e.g., processors with fewer cores for mobile devices and processors with more cores for servers). For example, depending on the type of computing device 400, the processor may be an Advanced RISC Machines (ARM) processor implemented using Reduced Instruction Set Computing (RISC) or an x86 processor implemented using Complex Instruction Set Computing (CISC). The computing device 400 may include one or more CPUs 406 in addition to one or more microprocessors or supplementary co-processors, such as math co-processors.

In addition to or alternatively from the CPU(s) 406, the GPU(s) 408 may be configured to execute at least some of the computer-readable instructions to control one or more components of the computing device 400 to perform one or more of the methods and/or processes described herein. One or more of the GPU(s) 408 may be an integrated GPU (e.g., with one or more of the CPU(s) 406 and/or one or more of the GPU(s) 408 may be a discrete GPU. In embodiments, one or more of the GPU(s) 408 may be a coprocessor of one or more of the CPU(s) 406. The GPU(s) 408 may be used by the computing device 400 to render graphics (e.g., 3D graphics) or perform general purpose computations. For example, the GPU(s) 408 may be used for General-Purpose computing on GPUs (GPGPU). The GPU(s) 408 may include hundreds or thousands of cores that are capable of handling hundreds or thousands of software threads simultaneously. The GPU(s) 408 may generate pixel data for output images in response to rendering commands (e.g., rendering commands from the CPU(s) 406 received via a host interface). The GPU(s) 408 may include graphics memory, such as display memory, for storing pixel data or any other suitable data, such as GPGPU data. The display memory may be included as part of the memory 404. The GPU(s) 408 may include two or more GPUs operating in parallel (e.g., via a link). The link may directly connect the GPUs (e.g., using NVLINK) or may connect the GPUs through a switch (e.g., using NVSwitch). When combined together, each GPU 408 may generate pixel data or GPGPU data for different portions of an output or for different outputs (e.g., a first GPU for a first image and a second GPU for a second image). Each GPU may include its own memory or may share memory with other GPUs.

In addition to or alternatively from the CPU(s) 406 and/or the GPU(s) 408, the logic unit(s) 420 may be configured to execute at least some of the computer-readable instructions to control one or more components of the computing device 400 to perform one or more of the methods and/or processes described herein. In embodiments, the CPU(s) 406, the GPU(s) 408, and/or the logic unit(s) 420 may discretely or jointly perform any combination of the methods, processes and/or portions thereof. One or more of the logic units 420 may be part of and/or integrated in one or more of the CPU(s) 406 and/or the GPU(s) 408 and/or one or more of the logic units 420 may be discrete components or otherwise external to the CPU(s) 406 and/or the GPU(s) 408. In embodiments, one or more of the logic units 420 may be a coprocessor of one or more of the CPU(s) 406 and/or one or more of the GPU(s) 408.

Examples of the logic unit(s) 420 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 410 may include one or more receivers, transmitters, and/or transceivers that enable the computing device 400 to communicate with other computing devices via an electronic communication network, included wired and/or wireless communications. The communication interface 410 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 420 and/or communication interface 410 may include one or more data processing units (DPUs) to transmit data received over a network and/or through interconnect system 402 directly to (e.g., a memory of) one or more GPU(s) 408.

The I/O ports 412 may enable the computing device 400 to be logically coupled to other devices including the I/O components 414, the presentation component(s) 418, and/or other components, some of which may be built in to (e.g., integrated in) the computing device 400. Illustrative I/O components 414 include a microphone, mouse, keyboard, joystick, game pad, game controller, satellite dish, scanner, printer, wireless device, etc. The I/O components 414 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 400. The computing device 400 may be include depth cameras, such as stereoscopic camera systems, infrared camera systems, RGB camera systems, touchscreen technology, and combinations of these, for gesture detection and recognition. Additionally, the computing device 400 may include accelerometers or gyroscopes (e.g., as part of an inertia measurement unit (IMU)) that enable detection of motion. In some examples, the output of the accelerometers or gyroscopes may be used by the computing device 400 to render immersive augmented reality or virtual reality.

The power supply 416 may include a hard-wired power supply, a battery power supply, or a combination thereof. The power supply 416 may provide power to the computing device 400 to enable the components of the computing device 400 to operate.

The presentation component(s) 418 may include a display (e.g., a monitor, a touch screen, a television screen, a heads-up-display (HUD), other display types, or a combination thereof), speakers, and/or other presentation components. The presentation component(s) 418 may receive data from other components (e.g., the GPU(s) 408, the CPU(s) 406, DPUs, etc.), and output the data (e.g., as an image, video, sound, etc.).

### Example Data Center

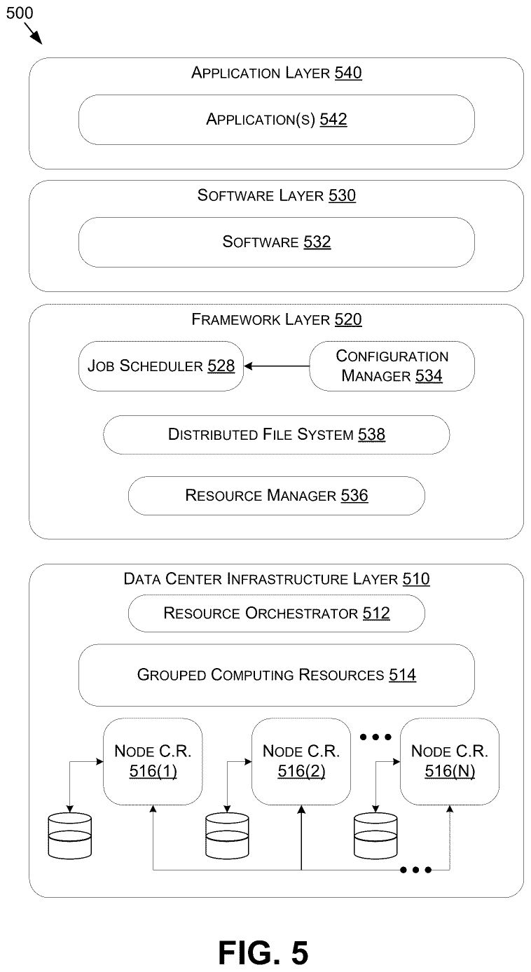

FIG. 5 illustrates an example data center 500 that may be used in at least one embodiments of the present disclosure. The data center 500 may include a data center infrastructure layer 510, a framework layer 520, a software layer 530, and/or an application layer 540.

As shown in FIG. 5, the data center infrastructure layer 510 may include a resource orchestrator 512, grouped computing resources 514, and node computing resources (“node C.R.s”) 516(1)-516(N), where “N” represents any whole, positive integer. In at least one embodiment, node C.R.s 516(1)-516(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 516(1)-516(N) may correspond to a server having one or more of the above-mentioned computing resources. In addition, in some embodiments, the node C.R.s 516(1)-5161(N) may include one or more virtual components, such as vGPUs, vCPUs, and/or the like, and/or one or more of the node C.R.s 516(1)-516(N) may correspond to a virtual machine (VM).

In at least one embodiment, grouped computing resources 514 may include separate groupings of node C.R.s 516 housed within one or more racks (not shown), or many racks housed in data centers at various geographical locations (also not shown). Separate groupings of node C.R.s 516 within grouped computing resources 514 may include grouped compute, network, memory or storage resources that may be configured or allocated to support one or more workloads. In at least one embodiment, several node C.R.s 516 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 512 may configure or otherwise control one or more node C.R.s 516(1)-516(N) and/or grouped computing resources 514. In at least one embodiment, resource orchestrator 512 may include a software design infrastructure (SDI) management entity for the data center 500. The resource orchestrator 512 may include hardware, software, or some combination thereof.

In at least one embodiment, as shown in FIG. 5, framework layer 520 may include a job scheduler 528, a configuration manager 534, a resource manager 536, and/or a distributed file system 538. The framework layer 520 may include a framework to support software 532 of software layer 530 and/or one or more application(s) 542 of application layer 540. The software 532 or application(s) 542 may respectively include web-based service software or applications, such as those provided by Amazon Web Services, Google Cloud and Microsoft Azure. The framework layer 520 may be, but is not limited to, a type of free and open-source software web application framework such as Apache Spark™ (hereinafter “Spark”) that may utilize distributed file system 538 for large-scale data processing (e.g., “big data”). In at least one embodiment, job scheduler 528 may include a Spark driver to facilitate scheduling of workloads supported by various layers of data center 500. The configuration manager 534 may be capable of configuring different layers such as software layer 530 and framework layer 520 including Spark and distributed file system 538 for supporting large-scale data processing. The resource manager 536 may be capable of managing clustered or grouped computing resources mapped to or allocated for support of distributed file system 538 and job scheduler 528. In at least one embodiment, clustered or grouped computing resources may include grouped computing resource 514 at data center infrastructure layer 510. The resource manager 536 may coordinate with resource orchestrator 512 to manage these mapped or allocated computing resources.

In at least one embodiment, software 532 included in software layer 530 may include software used by at least portions of node C.R.s 516(1)-516(N), grouped computing resources 514, and/or distributed file system 538 of framework layer 520. One or more types of software may include, but are not limited to, Internet web page search software, e-mail virus scan software, database software, and streaming video content software.

In at least one embodiment, application(s) 542 included in application layer 540 may include one or more types of applications used by at least portions of node C.R.s 516(1)-516(N), grouped computing resources 514, and/or distributed file system 538 of framework layer 520. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 534, resource manager 536, and resource orchestrator 512 may implement any number and type of self-modifying actions based on any amount and type of data acquired in any technically feasible fashion. Self-modifying actions may relieve a data center operator of data center 500 from making possibly bad configuration decisions and possibly avoiding underutilized and/or poor performing portions of a data center.

The data center 500 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 500. In at least one embodiment, trained or deployed machine learning models corresponding to one or more neural networks may be used to infer or predict information using resources described above with respect to the data center 500 by using weight parameters calculated through one or more training techniques, such as but not limited to those described herein.

In at least one embodiment, the data center 500 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 400 of FIG. 4—e.g., each device may include similar components, features, and/or functionality of the computing device(s) 400. In addition, where backend devices (e.g., servers, NAS, etc.) are implemented, the backend devices may be included as part of a data center 500, an example of which is described in more detail herein with respect to FIG. 5.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 400 described herein with respect to FIG. 4. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. One or more processors comprising:
one or more circuits to:
identify a plurality of shapes for a layout plan corresponding to an image;
allocate a stencil buffer for the image, the stencil buffer comprising a stencil sample for at least one point of the image;
generate, using the stencil buffer, an indication of a number of the plurality of shapes that overlap the at least one point; and
modify the layout plan based at least on the indication of the number of the plurality of shapes that overlap the at least one point.

2. The one or more processors of claim 1, wherein the one or more circuits are to:
generate a coverage image based at least on the image and the indication.

3. The one or more processors of claim 1, wherein the one or more circuits are to:
determine, using an occlusion query, an estimate of an area of a first shape of the plurality of shapes that overlaps at least one second shape of the plurality of shapes.

4. The one or more processors of claim 1, wherein the one or more circuits are to:
generate the stencil sample to include a winding number calculated for a first shape of the plurality of shapes with respect to the at least one point.

5. The one or more processors of claim 4, wherein the first shape is represented as a path, and wherein the one or more processors are to:
calculate the winding number based at least on the path corresponding to the first shape.

6. The one or more processors of claim 1, wherein the one or more circuits are to:
encode the indication of the number of the plurality of shapes that overlap the at least one point, in the stencil sample of the stencil buffer corresponding to the at least one point.

7. The one or more processors of claim 1, wherein the indication comprises one of three states including (i) an indication that none of the plurality of shapes overlap the at least one point, (ii) an indication that one of the plurality of shapes overlap the at least one point, and (iii) an indication that two or more of the plurality of shapes overlap the at least one point.

8. The one or more processors of claim 1, wherein the stencil buffer comprises a plurality of stencil samples respectively corresponding to each point of a plurality of points of the image, and wherein the one or more circuits are to:
generate, for one or more stencil samples of the plurality of stencil samples, a respective indication of a number of the plurality of shapes that overlap a respective point of the plurality of points.

9. The one or more processors of claim 8, wherein the one or more circuits are to:
generate the indication of the number of the plurality of shapes that overlap the at least one point based at least on a first winding number generated for a first shape of the plurality of shapes and a second winding number generated for a second shape of the plurality of samples.

10. The one or more processors of claim 1, wherein the one or more processors are comprised in at least one of:
a system implemented at least partially in a data center;
a system implemented at least partially using cloud computing resources;
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system implemented using an edge device;
a system implemented using a robot;
a system for performing conversational AI operations;
a system for performing generative AI operations using a large language model (LLM);
a system for performing generative AI operations using a video language model (VLM);
a system for performing generative AI operations using a multimodal language model;
a system for generating synthetic data;
a system incorporating one or more virtual machines (VMs);
a system using or deploying one or more inference microservices; or
a system that incorporates one or more machine learning models deployed in a service or microservice along with an OS-level virtualization package (e.g., a container).

11. The one or more processors of claim 1, wherein the layout plan corresponds to a planned layout for at least one of:
a circuit layout;
a printed circuit board layout;
an integrated circuit packaging design layout;
a microchip design layout;
a factory layout;
a product layout; or
an architecture structure layout.

12. A system, comprising:
one or more processors to:
allocate a stencil buffer comprising a plurality of samples for an image comprising a plurality of shapes, each sample of the plurality of samples corresponding to a respective position of the image;
update each sample the plurality of samples based on the plurality of shapes to generate an updated plurality of samples;
generate an estimated overlap area of at least two of the plurality of shapes based on the updated plurality of samples; and
update a layout plan of the plurality of shapes based at least on the estimated overlap area.

13. The system of claim 12, wherein each sample of the plurality of samples comprises a first number of bits corresponding to a respective winding number.

14. The system of claim 13, wherein the one or more processors are to:
update the respective winding number of a first sample of the plurality of sample based on a first shape of the plurality of shapes.

15. The system of claim 14, wherein each sample of the plurality of samples comprises at least one bit corresponding to an overlap, and wherein the one or more processors are to:
update the at least one bit of the first sample based on the respective winding number of the first sample.

16. The system of claim 12, wherein the one or more processors are to:
generate the estimated overlap area based on an occlusion query of the stencil buffer.

17. The system of claim 12, wherein each of the plurality of shapes is defined as a filled path.

18. The system of claim 12, wherein the system is comprised in at least one of:
a system implemented at least partially in a data center;
a system implemented at least partially using cloud computing resources;
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system implemented using an edge device;
a system implemented using a robot;
a system for performing conversational AI operations;
a system for performing generative AI operations using a large language model (LLM);
a system for performing generative AI operations using a video language model (VLM);
a system for performing generative AI operations using a multimodal language model;
a system for generating synthetic data;
a system incorporating one or more virtual machines (VMs);
a system using or deploying one or more inference microservices; or
a system that incorporates one or more machine learning models deployed in a service or microservice along with an OS-level virtualization package (e.g., a container).

19. A method, comprising:
identifying, using one or more processors, a plurality of shapes for a layout plan corresponding to an image;
allocating, using the one or more processors, a stencil buffer for the image, the stencil buffer comprising a stencil sample for at least one point of the image; and
generating, using the one or more processors, using the stencil buffer, an indication of a number of the plurality of shapes that overlap the at least one point.

20. The method of claim 19, further comprising:
generating, using the one or more processors, a coverage image based at least on the image and the indication.

21. The method of claim 20, further comprising:
determining, using the one or more processors, using an occlusion query, an estimate of an area of a first shape of the plurality of shapes that overlaps at least one second shape of the plurality of shapes.
